(19) United States
(12) Patent Application Publication
(10) Pub. No.: US 2008/0272390 A1
(43) Pub. Date: Nov. 6, 2008

(54) LED APPARATUS

(75) Inventors: David Shau Chew Wang, Taipei City (TW); Jyh Ming Yu, Kaohsiung City (TW); Jen Chien Wang, Sinjhuang City (TW); Hsieh Chang Huang, Toufen Town (TW)

Correspondence Address: CONNOLLY BOVE LODGE & HUTZ LLP, 1875 EYE STREET, N.W., SUITE 1100, WASHINGTON, DC, 20006, US

(73) Assignee: POLYTRONICS TECHNOLOGY CORPORATION, Hsinchu (TW)

(21) Appl. No.: 11/969,507

(22) Filed: Jan. 4, 2008

(30) Foreign Application Priority Data
May 4, 2007 (TW) 096207106

(51) Int. Cl. H01L 33/00

(52) U.S. Cl. 257/99; 257/E33.057

(57) ABSTRACT

An LED apparatus comprises a base, an LED device, an electrode member and an insulation layer. The base has a bevel side to be embedded with a corresponding receiving base for electrical conduction of an electrode (e.g., a negative electrode). The LED device is placed on an upper surface of the base. The electrode member comprising a metal rod and an electrode plate is connected to the LED device for electrical conduction of an electrode (e.g., a positive electrode). The insulation layer is placed between the electrode plate of the electrode member and the base for electrical insulation. The bevel side of the base can be modified as desired, and is generally less than 10 degrees, and preferably less than 5 degrees, and may be less than 3 degrees if needed.

### BACKGROUND OF THE INVENTION

(A) Field of the Invention

The present invention relates to a light emitting diode (LED) apparatus.

(B) Description of the Related Art

In recent years, white LEDs have become a very popular new product attracting widespread attention all over the world. Because white LEDs offer the advantages of small size, low power consumption, long life, and quick response speed, the problems of conventional incandescent bulbs can be solved. Therefore, applications of LEDs in backlight sources of displays, mini-projectors, illumination, and car lamp sources are becoming increasingly important in the market.

At present, Europe, the United States, Japan, and other countries increasingly agree on the importance of energy conservation and environmental protection, and actively develop the white LED as a new light source for illumination in this century. Currently, energy is imported in many countries, so it is worthwhile to develop the white LED in the illumination market. Based on the evaluation of experts, if all the incandescent lamps in Japan are replaced with white LEDs, the amount of electric power generated by two power plants could be conserved each year and the amount of corresponding reduction in fuel consumption would be of around one billion liters. Furthermore, carbon dioxide output during electrical power generation is also reduced, thereby reducing the greenhouse effect. Therefore, countries in Europe, America, and Japan have devoted a lot of manpower to white LED development. It is predicted that white LEDs can be substituted for conventional illuminating apparatuses within ten years.

However, with regard to a high power LED for illumination, merely 15-20% of the input power of the LED is converted into light, and the rest of the input power is converted into heat. If the heat cannot be dissipated into the environment quickly, the temperature of the LED device will become so high that the luminous intensity and service life are negatively affected. Therefore, the issue of heat management of the LED device attracts a lot of attention.

Referring to FIG. 1, a traditional LED apparatus 10 comprises an LED device 11 and a connector disk 16. The LED device 11 comprises an LED die 13 packaged in colloid 14 and carried by a base 12. Two electrode strips 15 are formed at two sides of the base 12 and serve as the positive and negative electrodes of the LED device 11. The LED device 11 is formed on the connector disk 16 for electrical conduction and heat dissipation.

However, the heat dissipation of the traditional LED apparatus 10 is not good; thus it creates many problems for high efficiency LED applications. Moreover, the assembly of the LED apparatus 10 is complicated; the electrode strips 15 of the LED device 11 have to be soldered for electrical conduction, which is detrimental to the enhancement of production efficiency and cost reduction.

### SUMMARY OF THE INVENTION

The present invention is mainly directed to provide an LED apparatus. By using a bevel design, the LED apparatus can be embedded with a corresponding receiving base. In addition to easy assembly, the manufacturing cost can be reduced due to the use of a simple structure. Moreover, the embedded design offers superior heat sink effect, so that the heat dissipation of the LED apparatus can be increased.

In accordance with the present invention, an LED apparatus comprises a base, an LED device, an electrode member and an insulation layer. The base has a bevel side to be embedded with a corresponding receiving base and serves as an electrode (e.g., a negative electrode) for electrical conduction. The LED device is placed on an upper surface of the base. The electrode member is connected to the LED device and serves as an electrode (e.g., a positive electrode) for electrical conduction. The insulation layer is placed between the electrode plate of the electrode member and the base for electrical insulation.

In an embodiment, the base is a cylinder with a wide top and a narrow bottom, and the diameter of the electrode plate is smaller than that of the bottom surface of the base; thereby the electrode plate is electrically insulated from the receiving base after the LED apparatus is embedded with the receiving base.

The bevel side of the base can be adjusted if desired. Generally, the angle of the bevel side is less than 10 degrees, and preferably less than 5 degrees, and an angle less than 3 degrees may be used also if needed.

The LED apparatus of the present invention is of a simple structure, and can be directly embedded with the receiving base, so screws are not needed. In addition, the bevel side of the base is entirely in contact with the receiving base; therefore the efficiency of electrical conduction or heat conduction therebetween can be increased significantly. As a result, efficient heat conduction can be maintained even without the use of heat conductive glue at the interface.

### BRIEF DESCRIPTION OF THE DRAWINGS

FIG. 1 illustrates a known LED apparatus;

FIGS. 2A and 2B illustrate the LED apparatus in accordance with an embodiment of the present invention;

FIG. 3 is an explosive diagram of the LED apparatus of the present invention; and

FIGS. 4, 5A and 5B illustrate the applications of the LED apparatus of the present invention.

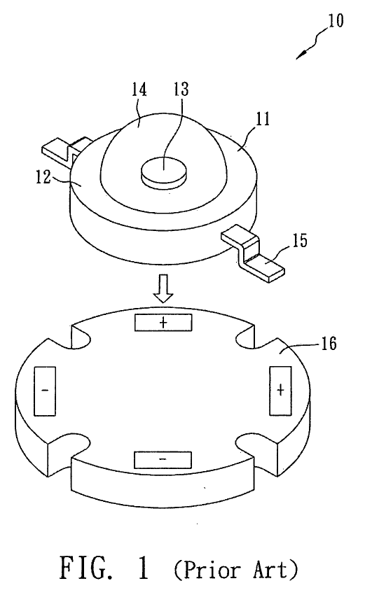

### DETAILED DESCRIPTION OF THE INVENTION

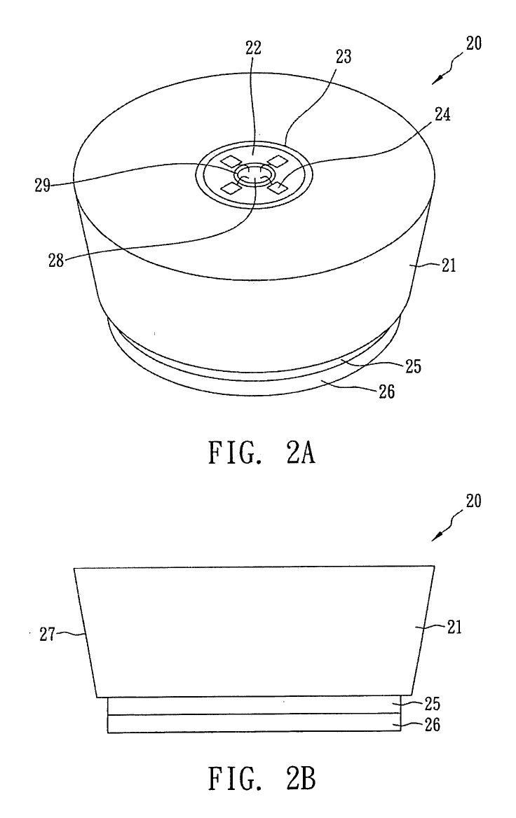

FIG. 2A illustrates the LED apparatus in accordance with an embodiment of the present invention, and FIG. 2B is a side view of the LED apparatus. An LED apparatus 20 comprises a base 21, an LED device 22, an insulation layer 25 and an electrode member including a metal rod 28 and an electrode plate 26. The LED device 22 comprises a plurality of LED dies 24 formed on the surface of the base 21 and packaged in the area defined by a frame 23 by colloid. The LED die 24 comprises a first electrode electrically connected to the base 21 and a second electrode electrically connected to the top of the metal rod 28. The electrode plate 26 and the metal rod 28 serve as the positive electrode of the LED apparatus 20, whereas the base 21 serves as the negative electrode of the LED apparatus 20. The insulation layer 25 is stacked between the base 21 and the electrode plate 26, and a hollow insulation tube 29 is placed between the base 21 and the metal rod 28 for the insulation between positive and negative electrodes.

The LED apparatus 20 is designed to be embedded with a receiving base, and therefore the base 21 is a cylinder with a wide top and a narrow bottom, i.e., the side 27 is beveled. The angle of the bevel with reference to a vertical line is less than 10 degrees, and preferably less than 5 degrees, and may be less than 3 degrees if needed. Consequently, the LED apparatus can be pressed into and embedded with a receiving base with a corresponding bevel design.

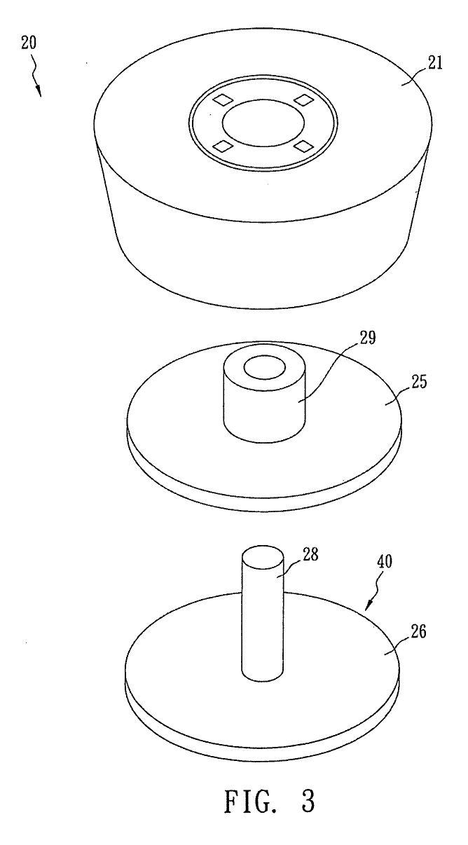

FIG. 3 is an explosive illustration of the LED apparatus 20. The electrode plate 26 and metal rod 28 constitute the electrode member 40. The metal rod 28 is placed at the center of the electrode plate 26 and penetrates the base 21, and is connected to the LED device 22 for electrical conduction of a positive electrode. The center of the insulation layer 25 is provided with a hollow insulation tube 29 for electrical insulation between the metal rod 28 and the base 21.

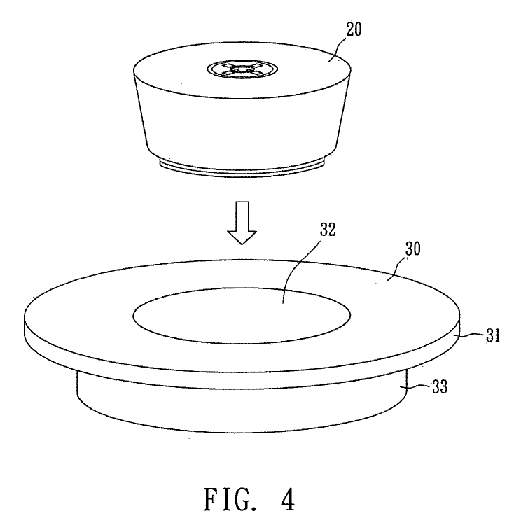

Referring to FIG. 4, a receiving base 30 (or adapter) comprises a ring 33 and a flange 31. The angle of an inner side 32 of the receiving base 30 corresponds to the angle of the bevel side 27 of the LED apparatus 20, and as a consequence the LED apparatus 20 can be smoothly embedded with the receiving base 30. The diameter (or width) of the insulation layer 25 and the electrode plate 26 is smaller than the diameter of the bottom of base 21 (see FIG. 2B). Therefore, when the LED apparatus 20 is embedded with the receiving base 30, the side 27 of the base 21 will tightly contact the inner side 32 of the receiving base 30 for electrical conduction of a negative electrode and heat dissipation. The electrode plate 26 does not contact the ring 33 and serves as a positive electrode.

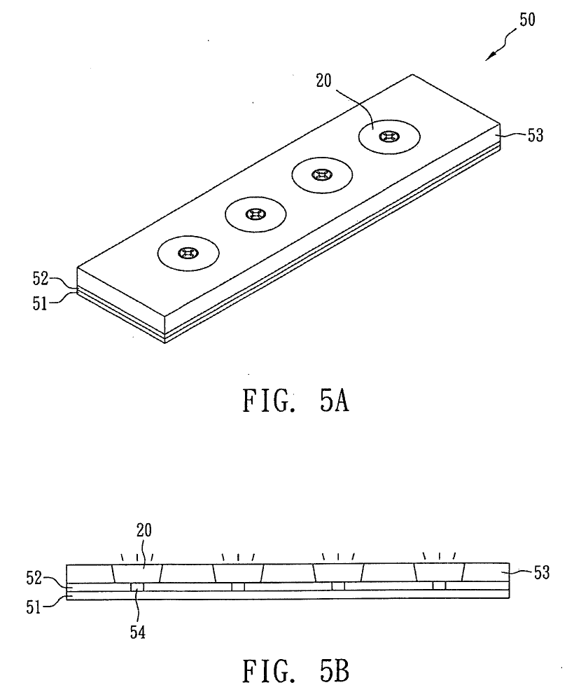

FIG. 5A illustrates an embodiment for the application of the LED apparatus of the present invention, and FIG. 5B is the cross-sectional view of the subject shown in FIG. 5A. An LED module 50 comprises four LED apparatuses 20 embedded with a body 53 serving as a negative electrode, and an electrode plate 51 below the body 53 serves as a positive electrode. An insulation layer 52 is formed between the body 53 and the electrode plate 51 for insulation between positive and negative electrodes. Conductive terminals 54 are formed below the LED apparatuses 20 for connecting the LED apparatuses 20 and the electrical plate 51 serving as the positive electrode.

According to the design of the present invention, the bottom and the side of the LED apparatus serve as the positive and negative electrodes thereof; thus electrode strips are not needed. The LED apparatus can be easily embedded with the corresponding receiving base, so any combination process such as soldering is not needed. Therefore, the assembly of the LED apparatus of the present invention can be tremendously simplified, thereby reducing manufacturing cost.

The above-described embodiments of the present invention are intended to be illustrative only. Numerous alternative embodiments may be devised by those skilled in the art without departing from the scope of the following claims.

What is claimed is:

1. An LED apparatus, comprising:
a base with a bevel side for being embedded with a corresponding receiving base;
an LED device placed on an upper surface of the base and having a first electrode connected to the base;
an electrode member comprising an electrode plate and a metal rod and being electrically connected to a second electrode of the LED device; and
an insulation layer formed between the electrode plate and the base for electrical insulation.

2. The LED apparatus of claim 1, wherein the base is a cylinder with a wide top and a narrow bottom.

3. The LED apparatus of claim 1, wherein the diameter of the electrode plate is smaller than the diameter of the bottom of the base and thereby the electrode plate and the receiving base are electrically insulated after the LED apparatus is embedded with the corresponding receiving base.

4. The LED apparatus of claim 1, wherein the angle of the bevel side is less than 10 degrees with reference to a vertical line.

5. The LED apparatus of claim 1, wherein the angle of the bevel side is less than 5 degrees with reference to a vertical line.

6. The LED apparatus of claim 1, wherein the electrode member serves as a positive electrode of the LED device and the bevel side of the base serves as a negative electrode of the LED device.

7. The LED apparatus of claim 1, wherein the metal rod is formed at the center of the electrode plate, penetrates the base and is electrically connected to the LED device.

8. The LED apparatus of claim 1, wherein the insulation layer has a hollow insulation tube formed at the center of the insulation layer for electrical insulation between the metal rod and the base.
